(19) United States
(12) Patent Application Publication
(10) Pub. No.: US 2025/0117556 A1
(43) Pub. Date: Apr. 10, 2025

(54) CRAMMED TRAINING FOR MOLECULAR COMPUTATION MODELS

(71) Applicant: Genentech, Inc., South San Francisco, CA (US)

(72) Inventors: Nathan Christopher FREY, South San Francisco, CA (US); Aya Abdelsalam Attia Abdelsalam ISMAIL, Secaucus, NJ (US)

(21) Appl. No.: 18/907,387

(22) Filed: Oct. 4, 2024

Related U.S. Application Data
(60) Provisional application No. 63/588,446, filed on Oct. 6, 2023.

(51) Int. Cl. G06F 30/27

(52) U.S. Cl. CPC G06F 30/27

(57) ABSTRACT

A method for crammed training of a molecular computation model includes receiving the molecular computation model. One or more crammed training constraints may be identified. An modification to the molecular computation model may be determined based on the one or more crammed training constraints. One or more training hyperparameters may be based on the one or more crammed training constraints. The molecular computation model having the architectural modification may be trained, or in some cases, pretrained in accordance with the one or more training hyperparameters. In some cases, the pretrained molecular computation model may undergo finetuning for a specific task such as predicting the function of a protein sequence or classifying a pair of protein sequences as an interacting pair or a non-interacting pair. Related systems and computer program products are also provided.

### CROSS REFERENCE TO RELATED APPLICATION

This application claims priority to U.S. Provisional Application No. 63/588,446, entitled “CRAMMED TRAINING FOR PROTEIN LANGUAGE MODELS” and filed on Oct. 6, 2023, the disclosure of which is incorporated herein by reference in its entirety.

### TECHNICAL FIELD

The subject matter described herein relates generally to computational molecular design and more specifically to techniques for reducing the computational burden of training a molecular computation model.

### INTRODUCTION

A molecule is a group of two more atoms held together by chemical bonds.

Molecules form the smallest identifiable unit into which a pure substance can be divided while still retaining the composition and chemical properties of that substance. Various properties of a molecule, including its ability to function as a therapeutic, may be contingent upon the conformation (or three-dimensional structure) of the molecule. One example of a molecule is a small molecule, which is a low-weight compound having a molecular weight between approximately 100 Daltons and 1000 Daltons. Small molecule therapeutics, which modulate biochemical processes to diagnose, treat, and prevent a gamut of illnesses, have been a cornerstone in modern pharmacology due to a number of compelling advantages. For example, small molecule drugs are capable of penetrating cell membranes to reach intracellular targets. Moreover, small molecule drugs are adaptable to a wide variety of therapeutic applications. For instance, a small molecule drug may be formulated as pills and capsules, intravenous or subcutaneous injectables, inhalational medicines, or suppositories. The development of the small molecule drug may further extend to tailoring various pharmacokinetic properties including liberation, absorption, distribution, metabolism, potency, efficacy, phenotypic effects, and excretion.

By contrast, large molecules (also known as biopharmaceuticals, biologicals, or biologics) can range between approximately 3000 Daltons and 150,000 Daltons in molecular weight. Large molecule drugs are often derivatives of natural human proteins, which modulate many essential cellular functions such as enzymatic reactions, transport of molecules, regulation and execution of a number of biological pathways, cell growth, proliferation, nutrient uptake, morphology, motility, intercellular communication, and/or the like. It is common for a single large molecule to have more than 1,300 amino acid residues, which are linked by peptide bonds to form one or more polypeptide. Due to their size and complexity, large molecule drugs are recombinantly produced by engineered cells instead of being chemically synthesized like the majority of small molecule drugs. Moreover, large molecule therapeutics are usually delivered through injection or infusion due to the ineffectiveness of oral administration. The development of a large molecule drug may entail designing one or more sequences of amino acid residues capable of binding to a target (e.g., a protein, a nucleic acid, and/or the like) with sufficient specificity and absent undesirable traits such as immunogenicity, self-association, instability, and/or the like.

### SUMMARY

Systems, methods, and articles of manufacture, including computer program products, are provided for crammed training of a molecular computation model. In one aspect, there is provided a system for crammed training of a molecular computation model that includes at least one memory and at least one data processor. The at least one memory may store instructions that result in operations when executed by the at least one processor. The operations may include: receiving a molecular computation model; identifying one or more crammed training constraints; determining, based at least on the one or more crammed training constraints, an architectural modification to the molecular computation model; determining, based at least on the one or more crammed training constraints, a training hyperparameter; and training, in accordance with the training hyperparameter, a molecular computation model having the architectural modification.

In one aspect, there is provided a computer-implemented method for machine learning enabled estimation of differences between protein molecules. The method may include: receiving a molecular computation model; identifying one or more crammed training constraints; determining, based at least on the one or more crammed training constraints, an architectural modification to the molecular computation model; determining, based at least on the one or more crammed training constraints, a training hyperparameter; and training, in accordance with the training hyperparameter, a molecular computation model having the architectural modification.

In another aspect, there is provided a computer program product including a non-transitory computer readable medium storing instructions. The instructions may cause operations may executed by at least one data processor. The operations may include: receiving a molecular computation model; identifying one or more crammed training constraints; determining, based at least on the one or more crammed training constraints, an architectural modification to the molecular computation model; determining, based at least on the one or more crammed training constraints, a training hyperparameter; and training, in accordance with the training hyperparameter, a molecular computation model having the architectural modification.

In some variations, one or more features disclosed herein including the following features can optionally be included in any feasible combination.

In some variations, the molecular computation model is a transformer-based protein language model.

In some variations, the training the molecular computation model having the architectural modification includes pretraining the molecular computation model to perform a task.

In some variations, the task includes predicting one or more masked tokens in a protein sequence.

In some variations, the training the molecular computation model having the architectural modification further includes finetuning the pretrained molecular computation model to perform a different task.

In some variations, the different task includes predicting a function of a protein sequence, or classifying a pair of protein sequences as an interacting pair or a non-interacting pair.

In some variations, the architectural modification includes removing a bias term added to a weighted input of the molecular computation model.

In some variations, the architectural modification includes removing at least one of a query bias term, a key bias term, or a value bias term from an attention block in the molecular computation model.

In some variations, the architectural modification further includes removing one or more bias terms from an intermediate linear layer of the molecular computation model.

In some variations, the training hyperparameter includes a learning rate schedule controlling changes in a learning rate of the molecular computation model during training.

In some variations, the training hyperparameter includes a learning rate controlling a magnitude to which a parameter of the molecular computation model is updated during each training iteration.

In some variations, the training hyperparameter includes a quantity of warmup iterations during which the molecular computation model is trained at a given learning rate.

In some variations, the training hyperparameter further includes a second learning rate to which the training of the molecular computation model transitions to after the quantity of warmup iterations are performed.

In some variations, the training hyperparameter further includes a mode and/or a rate at which the second learning rate anneals to a third learning rate during the training of the molecular computation model.

In some variations, the one or more crammed training constraints includes a compute budget comprising a threshold quantity of time and/or a threshold quantity of processing units.

In some variations, the training hyperparameter includes a maximum learning rate determined based on the compute budget.

In some variations, the training hyperparameter further includes a learning rate schedule which anneals the maximum learning rate to a minimum learning rate within the compute budget.

In some variations, the training hyperparameter includes gradient accumulation over a plurality of forward and backward passes through the molecular computation model in order to achieve a higher effective batch size.

Implementations of the current subject matter can include, but are not limited to, methods consistent with the descriptions provided herein as well as articles that comprise a tangibly embodied machine-readable medium operable to cause one or more machines (e.g., computers, etc.) to result in operations implementing one or more of the described features. Similarly, computer systems are also described that may include one or more processors and one or more memories coupled to the one or more processors. A memory, which can include a non-transitory computer-readable or machine-readable storage medium, may include, encode, store, or the like one or more programs that cause one or more processors to perform one or more of the operations described herein. Computer implemented methods consistent with one or more implementations of the current subject matter can be implemented by one or more data processors residing in a single computing system or multiple computing systems. Such multiple computing systems can be connected and can exchange data and/or commands or other instructions or the like via one or more connections, including, for example, to a connection over a network (e.g. the Internet, a wireless wide area network, a local area network, a wide area network, a wired network, or the like), via a direct connection between one or more of the multiple computing systems, etc.

The details of one or more variations of the subject matter described herein are set forth in the accompanying drawings and the description below. Other features and advantages of the subject matter described herein will be apparent from the description and drawings, and from the claims. While certain features of the currently disclosed subject matter are described for illustrative purposes in relation to protein language models trained to generate protein sequences, it should be readily understood that such features are not intended to be limiting. The claims that follow this disclosure are intended to define the scope of the protected subject matter.

### DESCRIPTION OF DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 depicts a system diagram illustrating an example of a molecular computation system, in accordance with some example embodiments;

FIG. 2 depicts a flowchart illustrating an example of a process for crammed training of a molecular computation model, in accordance with some example embodiments;

FIG. 3 depicts a block diagram illustrating an example of a computing system, in accordance with some example embodiments.

When practical, similar reference numbers denote similar structures, features, or elements.

### DETAILED DESCRIPTION

Molecular computation models, especially those leveraging artificial intelligence and machine learning, have been successfully deployed to streamline the drug discovery and development process. With greater accessibility to virtual molecular libraries for both small and large molecules as well as computational resources to support hyperdimensional computing, in silico methodologies are increasingly being regarded as either a supplement to or, in some cases, a replacement for costly wet lab experimentation. A growing variety of molecular computation models have been designed, trained, and applied toward tasks such as target discovery, molecule design, and virtual screening of candidate molecules. As one example, protein language models (pLMs), by providing a powerful framework for representation learning across the large, diverse protein universe, have become critical components for in silico prediction of protein structure and function.

Current state-of-the-art molecular computation models, such as protein language models (pLMs), require enormous compute budgets to scale up model size (e.g., for complex tasks) and training time (e.g., for large training datasets). For example, one training paradigm aimed to improve model performance when domain-or task-specific training data is limited includes pre-training a molecular computation model on a larger training dataset spanning multiple domains such that the molecular computation model is able to learn general molecular features before being fine-tuned on a smaller, domain-or task-specific training dataset. In the context of a protein language model (pLM), the pretraining may include training the protein language model on protein sequences from the general protein universe before finetuning the protein language model on antibody sequences (or protein sequences from another specific domain). In some cases, the pretraining may be unsupervised, meaning that the training dataset for pretraining the molecular computation model may be unlabeled whereas the finetuning of the molecular computation model may be performed in a supervised manner, using a labeled training dataset. The performance of the molecular computation model may be contingent on a number of factors, including choice of algorithm, data quality, feature selection, hyperparameter tuning, overall model architecture, and/or the like. Nevertheless, training the molecular computation model, particularly pretraining on a large, generic training dataset, is often too expensive and time-consuming to permit adequate exploration of the aforementioned factors to identify a combination that improves the performance of the fine-tuned molecular computation model.

Various embodiments of the present disclosure reduce the computational overhead through crammed training a molecular computation model. As used herein, crammed training refers to training the molecular computation model in a manner that enables the molecular computation model to be trained from scratch using a threshold quantity of compute budget. For example, in some cases, the threshold quantity of compute budget may be defined based on a threshold quantity of time and/or a threshold quantity of processing units (e.g., graphics processing units (GPUs)). To train the molecular computation model from scratch may mean the molecular computation model is being trained from an untrained state. In the untrained state, the molecular computation model has not undergone any training (such as pretraining) in which the parameters (e.g., weights, biases, and/or the like) of the molecular computation model are adjusted to reflect the patterns present within training data. Instead, to train the molecular computation model from scratch may include initializing the parameters (e.g., weights, biases, and/or the like) of the molecular computation model to random values such that adjustments are made to these random values during subsequent training of the molecular computation model. In some example embodiments, the computational overhead of training the molecular computation model may be reduced by applying one or more architectural modifications to the molecular computation model. For instance, in some cases, the one or more architectural modifications may include pruning one or more parameters, such as the bias term that is added to the weighted inputs to one or more neurons serving as interconnected processing nodes in the molecular computation model. Where the molecular computation model is a transformer-based language model operating on protein sequences, the one or more architectural modifications may include removing one or more query, key, and value biases from at least one constituent attention block. In some cases, bias terms may also be removed from one or more intermediate linear layers. As described in more details below, the removal of the one or more bias terms from the molecular computation model increase training efficiency, particular the training efficiency of the molecular computation model per token (or unit of training data) ingested by the molecular computation model. The elimination of the one or more bias terms may have minimal impact on the predictive or generative performance of the molecular computation model at least because the same information may be captured by the corresponding weights where the molecular computation model undergoes proper training.

In some example embodiments, in addition to or instead of the one or more architectural modifications, the computational overhead of training the molecular computation model may also be reduced by applying one or more modifications to the training protocol of the molecular computation model. In some cases, the one or more training modifications may include adjustments to one or more hyperparameters such as train-test data split ratio, learning rate, learning rate schedule, choice and configuration of optimization algorithm (e.g., gradient descent, stochastic gradient descent, Adam optimizer, and/or the like), quantity of training iterations (or epochs), batch size, and/or the like. For example, in some cases, the one or more training modifications may include increasing the batch size, which refers to the quantity of training samples processed before the molecular computation model is updated, while observing the constraints of crammed training. In some cases, the batch size may be increased, for example, to yield a higher effective batch size by at least accumulating the gradient and updating the molecular computation model after multiple forward and backward passes through the molecular computation model. Alternatively and/or additionally, the one or more training modifications may include tuning the learning rate schedule to increase (or maximize) learning rate without destabilizing the training of the molecular computation model. In this context, learning rate is a hyperparameter that controls the magnitude to which the parameters (e.g., weights, biases, and/or the like) of the molecular computation model are updated during each training iteration (or epoch). Learning rate may be varied throughout the training process, for example, in accordance with a learning rate schedule. In some cases, the learning rate schedule may be tuned to systematically reduce the learning rate during the course of training, for example, to near zero within the available compute budget. In some cases, the learning rate schedule may include one or more warmup rounds in which the molecular computation model is trained at a low learning rate before the learning rate is ramped up, for example, to a maximum learning rate that subsequently decays to near zero (or another minimum learning rate).

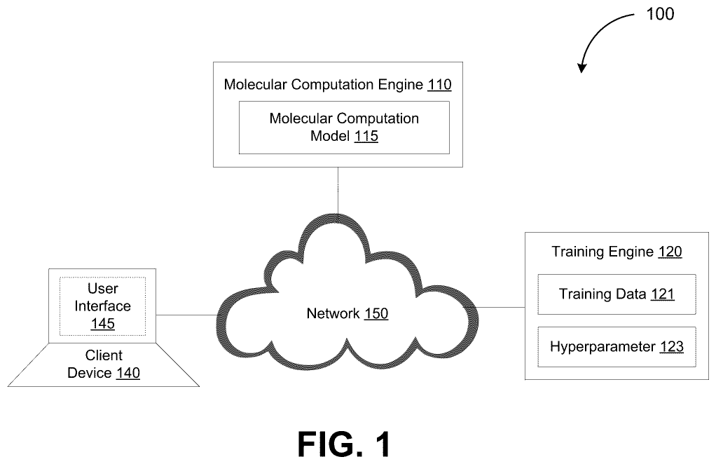

FIG. 1 depicts a system diagram illustrating an example of a molecular computation system 100, in accordance with some example embodiments. Referring to FIG. 1 the molecular computation system 110 may include a molecular computation engine 110, a training engine 120, and a client device 130. As shown in FIG. 1, the molecular computation engine 110, the training engine 120, and the client device 130 may be communicatively coupled via a network 140. In some cases, the client device 130 may be a processor-based device including, for example, a workstation, a desktop computer, a laptop computer, a smartphone, a tablet computer, a wearable apparatus, and/or the like. The network 140 may be a wired network and/or a wireless network including, for example, a local area network (LAN), a virtual local area network (VLAN), a wide area network (WAN), a public land mobile network (PLMN), the Internet, and/or the like.

Referring again to FIG. 1, the molecular computation engine 110 may include a molecular computation model 115. In some cases, the molecular computation model 115 may be trained to perform a molecular computation task including, for example, a predictive task, a generative task, and/or the like. For example, the molecular computation model 115 may be a protein language model (pLM) trained to determine the three-dimensional structure or, in some cases, one or more drug-like properties (e.g., expression, affinity, specificity, immunogenicity, in vivo stability, self-association, and/or the like) of a protein sequence ingested as input.

In some example embodiments, the training engine 120 may train the molecular computation model 115 to perform the molecular computation task while imposing one or more crammed training constraints. For example, in some cases, the one or more crammed training constraints may include a compute budget for training the molecular computation model 115. In some cases, the compute budget may be defined based on a threshold quantity of time and/or a threshold quantity of processing units (e.g., graphics processing units (GPUs)). Moreover, in some cases, the one or more crammed training constraints may require the training engine 120 to train the molecular computation model 115 from scratch, meaning that the molecular computation model 115 does not undergo any form of pretraining. Instead, the training engine 120 may pretrain the molecular computation model 115 on a generic, non-domain specific training dataset before the molecular computation model 115 is further finetuned on a domain-or task-specific training dataset. In instances where the molecular computation model 115 is a protein language model (pLM), for example, the pretraining may include training the molecular computation model 115 on protein sequences from the general protein universe before finetuning on antibody sequences (or protein sequences from another specific domain). As described in more details below, in some cases, the training engine 120 may determine one or more modifications, for example, to the architecture of the molecular computation model 115, the training protocol, and/or the like, to ensure that the molecular computation model 115 can be trained (e.g., pretrained with or without finetuning) without exceeding the compute budget.

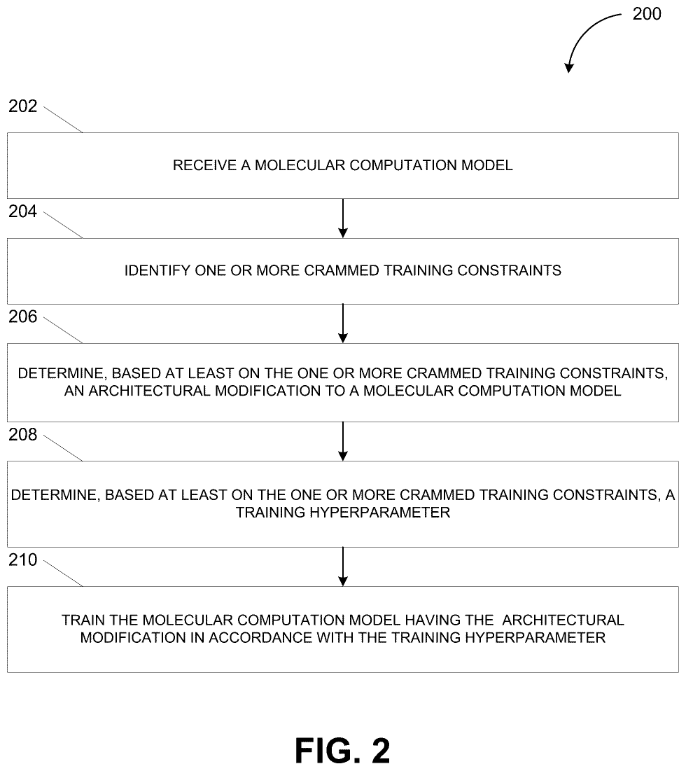

FIG. 2 depicts a flowchart illustrating an example of a process 200 for crammed training of a molecular computation model, in accordance with some example embodiments. Referring to FIGS. 1-2, the process 200 may be performed by the training engine 120 to train (e.g., pretrain with or without finetuning) the molecular computation model 115 while observing one or more crammed training constraints. As noted, a compute budget defined in terms of a threshold quantity of time and/or a threshold quantity of processing units (e.g., graphics processing units (GPUs)) is one example of a crammed training constraint. In some cases, the one or more crammed training constraints may further require the training engine 120 to train the molecular computation model 115 from scratch (e.g., without any pretraining) without exceeding the compute budget. As described in more details below, the training engine 120 may determine one or more modifications, such as to the architecture of the molecular computation model 115 and/or the training protocol, to ensure that the training (e.g., pretraining with or without finetuning) of the molecular computation model 115 conforms to the one or more crammed training constraints.

At 202, a molecular computation model is received. In some example embodiments, the molecular computation model that is received may be untrained, meaning that the molecular computation model has not been exposed to any training data. Prior to being trained, it should be appreciated that the parameters (e.g., weights, biases, and/or the like) of the molecular computation model may be initialized to random values that do not reflect any patterns present in any specific training dataset. In some cases, receiving the molecular computation model may include receiving access to the molecular computation model, which may be hosted in on-premise, in the cloud, or in a hybrid environment. In some cases, the molecular computation model may be a language model, such as a protein language model. In some cases, the molecular computation model may be a transformer-based language model. As described in more details below, in some cases, the molecular computation model may be received for training. In some cases, this training may include pretraining, with or without subsequent finetuning, while conforming to one or more crammed training constraints (e.g., compute budget). For example, the molecular computation model may be received in order to undergo pretraining for one task (e.g., predicting a type of amino acid residues corresponding to each masked token in a protein sequence) and, in some cases, finetuning for another task (e.g., predicting a function of a protein sequence, classifying a pair of protein sequences as an interacting pair or a non-interacting pair, and/or the like).

At 204, one or more crammed training constraints are identified. In some example embodiments, the one or more crammed training constraints may include a compute budget that is imposed on the training of the molecular computation model. In some cases, the compute budget may be defined based on a threshold quantity of time and/or a threshold quantity of processing units (e.g., graphics processing units (GPUs)). For example, in some cases, the one or more crammed training constraints may require the molecular computation model to be trained within the threshold quantity of time and/or using the threshold quantity of processing units (e.g., 24 GPU hours). In some cases, the one or more crammed training constraints may further require that the molecular computation model is trained from scratch, meaning that the molecular computation model does not undergo any pretraining prior to being trained without exceeding the allotted compute budget (e.g., within the threshold quantity of time and/or using the threshold quantity of processing units). It should be appreciated that pretraining the molecular computation model typically imposes significant compute cost whereas the compute cost associated with downstream finetuning tends to be negligible in comparison. For instance, in some cases, the finetuning of the molecular computation model may be accomplished using approximately 10% of the compute budget needed for pretraining the molecular computation model. Accordingly, in some cases, the one or more crammed training constraints may require that the molecular computation model is pretrained without any finetuning within the allotted compute budget. The allotted time budget may, in those instances, exclude the finetuning of the molecular computation model, which can be performed with unlimited compute budget (e.g., unlimited time, unlimited processing units, and/or the like). However it is also possible for the one or more crammed training constraints to impose a compute budget on the finetuning of the molecular computation model including, in some cases, require that the molecular computation model be pretrained as well as finetuned within the allotted compute budget.

At 206, an architectural modification to the molecular computation model is determined based at least on the one or more crammed training constraints. In some example embodiments, the architecture of the molecular computation model may be modified in order to accommodate the one or more crammed training constraints. In some cases, the compute requirement for training the molecular computation model may be reduced by at least pruning one or more parameters from the molecular computation model. For example, in some cases, the pruned parameters may include the bias term that is added to the weighted inputs of one or more neurons in the molecular computation model. Where the molecular computation model is a transformer-based language model, for instance, the pruned parameters may include one or more bias terms from an attention blocks, an intermediate linear layer, and/or the like. In some cases, removing some (or all) query, key, and value bias terms in some (or all) of the attention blocks in the molecular computation model may increase (or maximize) per-token training efficiency. In some cases, in addition to the query, key, and value bias terms in the attention blocks of the molecular computation model, some (or all) of the bias terms in some (or all) of the intermediate linear layers of the molecular computation model may also be removed.

At 208, one or more training hyperparameters are determined based at least on the one or more crammed training constraints. In some example embodiments, the one or more training hyperparameters may include the learning rate, which controls the magnitude to which the parameters (e.g., weights, biases, and/or the like) of the molecular computation model are updated during each training iteration (or epoch). Furthermore, in some cases, the one or more training parameters may include the learning rate schedule, which defines the scheduled changes to the learning rate throughout the training process. For example,

In some example, the learning rate may be an initial learning rate that is applied at the start of the training process or, in some cases, after a warmup process, while the learning rate schedule may specify a decay (e.g., a linear decay) of that initial learning rate such that the learning rate anneals to near zero (or another minimum learning rate) at the end of the training process. For example, the learning rate and the learning rate schedule may be determined based on the compute budget for training the molecular computation model and, in some cases, the total quantity if training iterations, such that the initial learning rate anneals to near zero (or another minimum learning rate) by the end of the training process. In some cases, the learning rate and the corresponding learning rate schedule may also be tuned to increase (or maximize) the learning rate without introducing training instabilities that can prevent the molecular computation model from reaching convergence, or a point in the training process in which the parameters (e.g., weights, biases, and/or the like) of the molecular computation model stabilize to values that produce accurate predictions for the training data. In some cases, the tuning of the learning rate schedule may include adjusting the quantity of warmup rounds in which the molecular computation model is trained at a lower learning rate than the aforementioned initial learning rate before the learning rate is ramped up, for example, to the initial learning rate (or the maximum learning rate in some cases) that then decays to near zero (or another minimum learning rate). In some cases, the tuning of the learning rate schedule may include adjusting the initial learning rate (e.g., the maximum learning rate). Alternatively and/or additionally, the learning rate schedule may be tuned by at least adjusting the mode (e.g., linear, non-linear) and/or rate of decay (e.g., from the initial or maximum learning rate).

In some example embodiments, the one or more training hyperparameters may include batch size (or effective batch size), which determines the quantity of training samples processed before the parameters (e.g., weights, biases, and/or the like) of the molecular computation model are updated. In some cases, batch size (or effective batch size) may be increased (or maximized) within the bounds of the one or more crammed training constraints by accumulating gradients and performing updates after multiple forward/backward passes. For example, where the batch size is set to 128 protein sequences with a maximum length of 512 tokens (large enough to accommodate most individual protein sequences in the training dataset), an effective batch size of 2048 protein sequences or 1,048,576 tokens may be achieved by accumulating gradients and updating the molecular computation model every 16 forward/backward passes. In this particular example, the 512 tokens representative of a protein sequence may include two special tokens denoting the start and the end of the protein sequence, while each of the 510 intervening tokens may encode a type of the amino acid residue occupying the corresponding position in the protein sequence.

In some example embodiments, the training of the molecular computation model may be further tuned to conform to the one or more crammed training constraints by modulating the training samples. For example, in some cases, the molecular computation model may undergo training (or pretraining) for masked language modeling, meaning that the molecular computation model is trained (or pretrained) to perform the task of predicting one or more masked tokens (e.g., the type of masked amino acid residues) in the protein sequences used as training samples. In some cases, the tuning may include adjusting the masking rate, which determines the quantity (or proportion) of masked tokens in each protein sequence serving as a training sample. For instance, in some cases, the masking rate may be increased (e.g., from 15% to 25% of the 512 tokens in each protein sequence) in order to increase training efficiency by increasing the difficulty of the task of identifying the masked tokens. In some cases, other training hyperparameters that may be tuned include the choice and hyperparameter configuration of optimization algorithm (e.g., gradient descent, stochastic gradient descent, Adam optimizer, and/or the like), quantity of training iterations (or epochs), and/or the like. In some cases, for example, the optimization algorithm may be Adam optimizer configured with β1=0.99, β2=0.98, and ϵ=10−12. In some cases, a gradient clipping value (e.g., 0.5) may be used to stabilize training (e.g., prevent an exploding gradient). Furthermore, in some cases, training may be performed with automated mixed precision, which utilizes representations in different numerical precisions such as a mix of single-precision (32-bit) and half-precision (16-bit) representations floating-point types, to further accelerate training and reduce memory footprint.

At 210, the molecular computation model having the architectural modification is trained in accordance with the one or more training hyperparameters. In some example embodiments, the molecular computation model that undergoes training may include one or more architectural modifications. One example of an architectural modification is the pruning of one or more parameters, such as bias terms, from one or more neurons (or interconnected processing nodes) in the molecular computation model. Furthermore, in some cases, the training of the molecular computation model may be performed in accordance with the one or more training hyperparameters including, for example, the learning rate, the learning schedule, and/or the like. As noted, the one or more architectural modifications may, along with the one or more training hyperparameters, ensure that the training of the molecular computation model satisfies the one or more crammed training criteria. For example, the one or more architectural modifications may reduce the compute requirement for training the molecular computation model such that the molecular computation model may be trained without exceeding the compute budget imposed by the one or more crammed training constraints. Moreover, in some cases, the learning rate and the learning rate schedule may be tuned to increase (or maximize) the learning rate without causing training instabilities and, in some cases, to anneal the learning rate to near zero at the end of the training process.

### Experimental Examples

A transformer-based molecular computation model was modified by removing all query, key, and value bias terms from every attention block as well as all bias terms in the intermediate linear layers. A hyperparameter sweep over a range of learning rates E [1×10⁻², 4×10⁻⁴] and a range of warmup iterations ϵ[100, 40000] was performed. The results of this ablation are shown in Table 1.

TABLE 1
molecular computation model crammed learning dynamics.

| Learning | Number of | Validation |
|---|---|---|
| Rate | Warmup Iterations | Perplexity ↓ |
| 0.001 | 1000 | 13.72 |
| 0.0004 | 1000 | 13.92 |
| 0.01 | 10000 | 13.96 |
| 0.001 | 100 | 14.10 |
| 0.001 | 10000 | 14.31 |
| 0.001 | 40000 | 14.88 |
| 0.004 | 1000 | 17.42 |
| 0.004 | 100 | 20.49 |

As shown in Table 1, the choice of learning rate and the quantity of warmup iterations had a significant impact on validation perplexity, which measures the uncertainty of the predictions made by the molecular computation model on the validation dataset. If the molecular computation model is performing well, it should exhibit low perplexity on both the training dataset as well as the validation dataset to indicate an ability to make accurate predictions across a range of inputs. In instances where the molecular computation model is overfitted, the training perplexity of the model would be low while the validation perplexity of the model is high. In this particular ablation experiment, validation perplexity ranged from 13.72 for the best performing model to 20.49 for the worst performing model with a vocabulary size (or quantity of unique tokens) of 33, with 20 unique tokens encoding the different types of amino acid residues (e.g., 20 canonical amino acid residues) and the remainder encoding unknown characters., special characters, and non-canonical amino acid residues. An optimal selection of hyperparameters should include a maximally high learning rate along with a learning rate schedule that prevents training instabilities and anneals the learning rate close to zero by the end of training. In this ablation experiment, the best performing model reached a maximum learning rate of 0.001 after 1000 warmup iterations before being gradually annealed over the remaining 49000 iterations.

In some cases, the transformer-based molecular computation model (Crammed pLM) was crammed pretrained to predict masked tokens in protein sequences before being finetuned for four downstream tasks: three protein fitness landscape inference (function prediction) tasks from the Fitness Landscape Inference for Proteins (FLIP) benchmark (GB1, AAV, and Meltome) and one protein-protein interaction (PPI) task. For the finetuning, the encoders of the transformer-based molecular computation models were frozen (e.g., to their pretrained state) while a two-layer multi-layer perceptron (MLP) with a feed-forward dimension of 256 was trained for each task at a constant learning rate of 4×10⁻⁵ and batch size of 128. Token embeddings from the pretrained molecular computation model are aggregated using mean pooling prior to being ingested by the multi-layer perceptron for the corresponding downstream task.

Tables 2, 3, and 4 show the results of downstream task evaluation. The FLIP benchmark contains many train/test splits based on edit distance and sequence similarity to provide a detailed evaluation of the model's ability to “generalize” in different realistic protein engineering settings. First, the downstream performance of the molecular computation model was evaluated using random or independent and identically distributed splits (between training and validation data) for the GB1 and AAV tasks. In this particular instance, 10% of the training dataset was randomly selected to serve as the validation dataset. The ability of the molecular computation model to generalize out-of-distribution was tested using a 2-vs-rest split for both the GB1 and AAV tasks. Because the Meltome dataset does not provide an independent and identically distributed split, a “mixed split” based on cluster components was used.

The protein-protein interaction (PPI) benchmark is for the specific task of classifying pairs of protein sequences as interacting or non-interacting. The Neglog dataset, which includes positive, interacting pairs as well as negative, non-interacting pairs augmented from Negatome 2.0, was used to test the crammed pretrained molecular computation model. An independent and identically distributed (or random) split of the Neglog dataset was made by randomly sampling 10% as the test dataset, 70% as the training dataset, and 20% as the validation dataset.

Tables 2 and 3 report the performance of the pretrained and finetuned molecular computation model on the validation datasets. It should be appreciated that downstream evaluation was performed without any hyperparameter tuning. Performance metrics for the pretrained and finetuned molecular computation model operating on test datasets performance are shown in Table 4 for all out-of-distribution splits.

TABLE 2
Downstream task evaluation with a 10% cramming time limit
on the finetuning. The FLIP tasks (GB1, AAV, and Meltome)
results are reported in Spearman correlation and the PPI task is
reported in area under the precision-recall curve (AUPRC).

| Model | GB1 | AAV | Meltome | PPI |
|---|---|---|---|---|
| Crammed pLM-67M | 0.53 | 0.76 | 0.34 | 0.78 |
| ESM2-8M | 0.59 | 0.81 | 0.42 | 0.86 |
| ESM2-150M | 0.55 | 0.78 | 0.29 | 0.88 |
| ESM2-3B | 0.40 | 0.62 | 0.20 | 0.85 |

TABLE 3
Downstream task evaluation with no time limit on finetuning.
The FLIP tasks (GB1, AAV, and Meltome) results are reported
in Spearman correlation and the PPI task is reported in area
under the precision-recall curve (AUPRC).

| Model | GB1 | AAV | Meltome | PPI |
|---|---|---|---|---|
| Crammed pLM-67M | 0.63 | 0.79 | 0.51 | 0.78 |
| ESM2-8M | 0.59 | 0.83 | 0.59 | 0.86 |
| ESM2-150M | 0.58 | 0.82 | 0.63 | 0.88 |
| ESM2-3B | 0.66 | 0.81 | 0.54 | 0.88 |

TABLE 4
FLIP downstream task evaluation (sp) with no time limit on out-
of-distribution test splits. Each model is compared with its randomly-
initialized baseline to highlight gains from pretraining.

| | Pretrained | | | Baseline (no pretraining) | | |
|---|---|---|---|---|---|---|
| Model | GB1 | AAV | Meltome | GB1 | AAV | Meltome |
| Crammed | 0.42 | 0.12 | 0.41 | 0.33 | −0.03 | 0.48 |
| pLM-67M | | | | | | |
| ESM2-8M | 0.16 | 0.29 | 0.29 | −0.02 | −0.10 | −0.19 |
| ESM2-150M | 0.16 | 0.38 | 0.44 | 0.17 | −0.13 | −0.21 |
| ESM2-3B | 0.19 | 0.20 | 0.36 | 0.30 | −0.10 | −0.23 |

The three baseline models are ESM2 models of size 8 million, 150 million, and 3billion parameters. These baseline models were trained on over 60 million unique protein sequences from UniRef50 and UniRef90, with an effective batch size of 2 million tokens. The learning rate was warmed up over 2,000 iterations to a peak value of 4×10⁻⁴ before being linearly decayed to 4×10⁻⁵ over 90% of the duration of training, for a total of 500,000training iterations. Notably, the 3-billion parameter ESM2-3B model was trained on 512NVIDIA V100 GPUs over 30 days, which is equivalent to 368,640 GPU hours. By contrast, the crammed trained molecular computation model (Crammed pLM-67M) was trained in 24 GPU hours, representing 0.0065% of the total training time of ESM2-3B model or a 15,000×speedup.

Table 2 reports the downstream performance of the finetuned molecular computation model where the finetuning is subject to a compute budget of 10% of the pretraining compute budget (or 2.4 GPU hours). In this regime, the results in Table 2 shows that downstream performance is inversely correlated with the size (or capacity) of the model (e.g., as quantified by number of parameters). While smaller models train faster and, in some cases, within the imposed compute budget (e.g., 2.4 GPU hours), model size (or capacity) does not compensate for this. In Table 3, downstream performance is shown for a regime in which the finetuning of the molecular computation model is not subject to any compute budget. In those instances, the molecular computation models were trained to convergence with early stopping to prevent overfitting. The crammed trained molecular computation model (Crammed pLM-67M) achieved comparable performance on the FLIP and PPI downstream task compared to the much larger ESM2 models. The crammed trained molecular computation model (Crammed pLM-67M) was able to achieve comparable performance to the much larger models while requiring a small fraction of the compute budget used to finetune the larger models.

Table 4 reports results on the out-of-distribution test dataset splits. The crammed trained molecular computation model (Crammed pLM-67M) outperformed the ESM baseline models on the GB1 and Meltome tasks, suggesting that 24 GPU hours of pretraining can effectively produce representations that generalize to out-of-distribution data. When each pretrained encoder is compared to its randomly initialized baseline, the results highlight the gains attributable to pretraining. The phenomenon in which crammed and non-crammed pretrained models performed worse than its randomly initialized counterpart may be due to the trainable multi-layer perceptron (MLP) driving performance more than the pretrained encoder. That many models were unable to generalize to out-of-distribution data regardless of the amount of pretraining indicate the need for a downstream task specific finetuning strategy as mean pooling, the global finetuning strategy selected here, is likely to be suboptimal for representing protein sequences for out-of-distribution landscape prediction tasks.

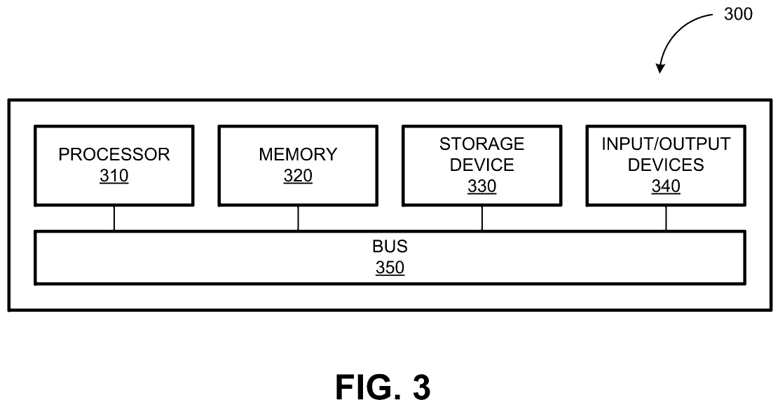

FIG. 3 depicts a block diagram illustrating an example of a computing system 300, in accordance with some example embodiments. Referring to FIGS. 1-3, the computing system 300 may be used to implement the molecule design engine 110, the selection engine 120, the laboratory equipment 130, the client device 140, and/or any components therein.

As shown in FIG. 3, the computing system 300 can include a processor 310, a memory 320, a storage device 330, and input/output devices 340. The processor 310, the memory 320, the storage device 330, and the input/output devices 340 can be interconnected via a system bus 350. The processor 310 is capable of processing instructions for execution within the computing system 300. Such executed instructions can implement one or more components of, for example, the molecule design engine 110, the selection engine 120, the laboratory equipment 130, the client device 140, and/or the like. In some example embodiments, the processor 310 can be a single-threaded processor. Alternately, the processor 310 can be a multi-threaded processor. The processor 310 is capable of processing instructions stored in the memory 320 and/or on the storage device 330 to display graphical information for a user interface provided via the input/output device 340.

The memory 320 is a computer readable medium such as volatile or non-volatile that stores information within the computing system 300. The memory 320 can store data structures representing configuration object databases, for example. The storage device 330 is capable of providing persistent storage for the computing system 300. The storage device 330 can be a floppy disk device, a hard disk device, an optical disk device, or a tape device, or other suitable persistent storage means. The input/output device 340 provides input/output operations for the computing system 300. In some example embodiments, the input/output device 340 includes a keyboard and/or pointing device. In various implementations, the input/output device 340 includes a display unit for displaying graphical user interfaces.

According to some example embodiments, the input/output device 340 can provide input/output operations for a network device. For example, the input/output device 340 can include Ethernet ports or other networking ports to communicate with one or more wired and/or wireless networks (e.g., a local area network (LAN), a wide area network (WAN), the Internet).

In some example embodiments, the computing system 300 can be used to execute various interactive computer software applications that can be used for organization, analysis and/or storage of data in various formats. Alternatively, the computing system 300 can be used to execute any type of software applications. These applications can be used to perform various functionalities, e.g., planning functionalities (e.g., generating, managing, editing of spreadsheet documents, word processing documents, and/or any other objects, etc.), computing functionalities, communications functionalities, etc. The applications can include various add-in functionalities or can be standalone computing products and/or functionalities. Upon activation within the applications, the functionalities can be used to generate the user interface provided via the input/output device 340. The user interface can be generated and presented to a user by the computing system 300 (e.g., on a computer screen monitor, etc.).

One or more aspects or features of the subject matter described herein can be realized in digital electronic circuitry, integrated circuitry, specially designed ASICs, field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and typically interact through a communication network. The relationship of client and server arises by virtue of computer programs running on the respective computers and having a client-server relationship to each other.

These computer programs, which can also be referred to as programs, software, software applications, applications, components, or code, include machine instructions for a programmable processor, and can be implemented in a high-level procedural and/or object-oriented programming language, and/or in assembly/machine language. As used herein, the term “machine-readable medium” refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” refers to any signal used to provide machine instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example, as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including acoustic, speech, or tactile input. Other possible input devices include touch screens or other touch-sensitive devices such as single or multi-point resistive or capacitive track pads, voice recognition hardware and software, optical scanners, optical pointers, digital image capture devices and associated interpretation software, and the like.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and subcombinations of the disclosed features and/or combinations and subcombinations of several further features disclosed above. In addition, the logic flows depicted in the accompanying figures and/or described herein do not necessarily require the particular order shown, or sequential order, to achieve desirable results. Other implementations may be within the scope of the following claims.

What is claimed is:

1. A system, comprising:
at least one data processor; and
at least one memory storing instructions, which when executed by the at least one data processor, result in operation comprising:
receiving a molecular computation model;
identifying one or more crammed training constraints;
determining, based at least on the one or more crammed training constraints, an architectural modification to the molecular computation model;
determining, based at least on the one or more crammed training constraints, a training hyperparameter; and
training, in accordance with the training hyperparameter, a molecular computation model having the architectural modification.

2. The system of claim 1, wherein the molecular computation model is a transformer-based protein language model.

3. The system of claim 1, wherein the training the molecular computation model having the architectural modification includes pretraining the molecular computation model to perform a task.

4. The system of claim 3, wherein the task includes predicting one or more masked tokens in a protein sequence.

5. The system of claim 3, wherein the training the molecular computation model having the architectural modification further includes finetuning the pretrained molecular computation model to perform a different task.

6. The system of claim 5, wherein the different task includes predicting a function of a protein sequence, or classifying a pair of protein sequences as an interacting pair or a non-interacting pair.

7. The system of claim 1, wherein the architectural modification includes removing a bias term added to a weighted input of the molecular computation model.

8. The system of claim 1, wherein the architectural modification includes removing at least one of a query bias term, a key bias term, or a value bias term from an attention block in the molecular computation model.

9. The system of claim 8, wherein the architectural modification further includes removing one or more bias terms from an intermediate linear layer of the molecular computation model.

10. The system of claim 1, wherein the training hyperparameter includes a learning rate schedule controlling changes in a learning rate of the molecular computation model during training.

11. The system of claim 1, wherein the training hyperparameter includes a learning rate controlling a magnitude to which a parameter of the molecular computation model is updated during each training iteration.

12. The system of claim 1, wherein the training hyperparameter includes a quantity of warmup iterations during which the molecular computation model is trained at a given learning rate.

13. The system of claim 12, wherein the training hyperparameter further includes a second learning rate to which the training of the molecular computation model transitions to after the quantity of warmup iterations are performed.

14. The system of claim 13, wherein the training hyperparameter further includes a mode and/or a rate at which the second learning rate anneals to a third learning rate during the training of the molecular computation model.

15. The system of claim 1, wherein the one or more crammed training constraints includes a compute budget comprising a threshold quantity of time and/or a threshold quantity of processing units.

16. The system of claim 15, wherein the training hyperparameter includes a maximum learning rate determined based on the compute budget.

17. The system of claim 16, wherein the training hyperparameter further includes a learning rate schedule which anneals the maximum learning rate to a minimum learning rate within the compute budget.

18. The system of claim 15, wherein the training hyperparameter includes gradient accumulation over a plurality of forward and backward passes through the molecular computation model in order to achieve a higher effective batch size.

19. A computer-implemented method, comprising:
receiving a molecular computation model;
identifying one or more crammed training constraints;
determining, based at least on the one or more crammed training constraints, an architectural modification to the molecular computation model;
determining, based at least on the one or more crammed training constraints, a training hyperparameter; and
training, in accordance with the training hyperparameter, the molecular computation model having the architectural modification.

20. A non-transitory computer readable medium storing instructions, which when executed by at least one data processor, result in operations comprising:
receiving a molecular computation model;
identifying one or more crammed training constraints;
determining, based at least on the one or more crammed training constraints, an architectural modification to the molecular computation model;
determining, based at least on the one or more crammed training constraints, a training hyperparameter; and
training, in accordance with the training hyperparameter, the molecular computation model having the architectural modification.
